(19) United States
(12) Patent Application Publication
(10) Pub. No.: US 2026/0176495 A1
(43) Pub. Date: Jun. 25, 2026

(54) POLISHING LIQUID FOR CMP, POLISHING LIQUID SET FOR CMP, AND POLISHING METHOD

(71) Applicant: Resonac Corporation, Tokyo (JP)

(72) Inventors: Yasushi KURATA, Tokyo (JP); Tomohiro IWANO, Tokyo (JP); Makoto MIZUTANI, Tokyo (JP); Kai SATO, Tokyo (JP); Masanori MAEDA, Tokyo (JP); Shigeki KUBOTA, Tokyo (JP); Junya SAKAGUCHI, Tokyo (JP); Yuto KURATA, Tokyo (JP); Keisuke INOUE, Tokyo (JP); Ayaka KUWATA, Tokyo (JP)

(21) Appl. No.: 18/857,665

(22) PCT Filed: Sep. 13, 2023
(86) PCT No.: PCT/JP2023/033427

§ 371 Date: Oct. 17, 2024

(51) Int. Cl. C09G 1/02; B24B 37/04; H10P 52/40

(52) U.S. Cl. CPC C09G 1/02; B24B 37/044; H10P 52/407

(57) ABSTRACT

A polishing liquid for CMP, the polishing liquid containing abrasive grains, a nitrogen-containing compound, and water, in which the abrasive grains include cerium-based particles, and the nitrogen-containing compound includes a compound A1 having a fused ring (a fused ring having an aromatic five-membered ring with one nitrogen atom), a compound A2 having a quinoline ring and one hydroxy group bonded to the quinoline ring, a compound A3 having an aromatic ring and a hydroxy group bonded to a nitrogen atom, or a compound A4 having a nitrogen-containing aromatic ring to which at least one selected from the group consisting of a hydroxy group and an amino group is bonded.

### TECHNICAL FIELD

The present disclosure relates to a polishing liquid for CMP (chemical mechanical polishing), a polishing liquid set for CMP, a polishing method, and the like.

### BACKGROUND ART

In the field of semiconductor manufacturing, along with high performance improvement of ultra LSI devices, there is a limit in achieving both high integration and high speed using a miniaturization technique which is an extension of a conventional technique. Therefore, while miniaturization of a semiconductor element is in progress, a technique for achieving high integration also in a vertical direction (that is, a technique for multilayered wiring) is being developed.

One of the most important techniques in a process of manufacturing a device having a multilayered wiring structure is a CMP technique. The CMP technique is a technique to planarize the surface of a base substrate obtained by forming a thin film on a substrate by chemical vapor deposition (CVD) or the like. For example, to secure the focal depth of lithography, planarization processing by CMP is essential. When the surface of the base substrate has unevenness, there are disadvantages in that focusing in an exposure step becomes impossible and a fine wiring structure cannot be sufficiently formed. In addition, in the process of manufacturing a device, the CMP technique is also applied to a step of forming an element isolation (inter-element isolation, STI: shallow trench isolation) region by polishing a plasma oxide film (BPSG, HDP-SiO₂, p-TEOS, and the like); a step of forming an ILD film (an interlayer insulating film, an insulating film that electrically insulates metal members (wiring and the like) in the same layer); and a step of planarizing a plug (for example, an Al—Cu plug) after a film containing silicon oxide is embedded in a metal wiring.

CIP is usually performed using a device capable of supplying a polishing liquid onto a polishing pad. Then, the surface of the base substrate is polished by pressing the base substrate against the polishing pad while supplying the polishing liquid between the surface of the base substrate and the polishing pad. As described above, in the CIP technique, the polishing liquid is one of the elemental techniques, and various polishing liquids have been developed so far to obtain a high-performance polishing liquid (refer to, for example, Patent Literature 1 below).

Among the steps to which the CIP technique as described above is applied, particularly in the CIP step of the ILD film, it is necessary to polish silicon oxide at a high polishing rate. Therefore, in the CMP step of the ILD film, a silica-based polishing liquid (a polishing liquid using abrasive grains including silica-based particles) having a high polishing rate is mainly used (refer to, for example, Patent Literature 2 below). However, in the silica-based polishing liquid, it tends to be difficult to control polishing scratches that cause a defect. In addition, along with the recent miniaturization of wiring, it is desirable to reduce polishing scratches even in the CMP step of the ILD film, but unlike the CMIP step of the insulating film for element isolation region, finish mirror polishing is not generally performed. Therefore, a study has been conducted to use a cerium-based polishing liquid (a polishing liquid using abrasive grains including cerium-based particles) generating fewer polishing scratches than those of the silica-based polishing liquid (refer to, for example, Patent Literature 3 below).

### CITATION LIST

### Patent Literature

Patent Literature 1: Japanese Unexamined Patent Publication No. 2008-288537
Patent Literature 2: Japanese Unexamined Patent Publication No. H9-316431
Patent Literature 3: Japanese Unexamined Patent Publication No. H10-102038

### SUMMARY OF INVENTION

### Technical Problem

However, in the cerium-based polishing liquid, it may be difficult to achieve a high polishing rate of silicon oxide, and particularly, in polishing of a patterned wafer having an uneven pattern constituted of a convex portion (for example, a line portion) and a concave portion (for example, a space portion), it may be difficult to achieve a high polishing rate of silicon oxide at the convex portion.

An object of one aspect of the present disclosure is to provide a polishing liquid for CMP capable of achieving a high polishing rate of silicon oxide at a convex portion in polishing of a patterned wafer having an uneven pattern. An object of another aspect of the present disclosure is to provide a polishing liquid set for CP for obtaining such polishing liquid for CP. An object of another aspect of the present disclosure is to provide a polishing method using such polishing liquid for CMP.

### Solution to Problem

The present disclosure relates to the following [1] to [17] and the like in some aspects.

[1] A polishing liquid for CMP, the polishing liquid containing: abrasive grains; a nitrogen-containing compound; and water, in which the abrasive grains include cerium-based particles, the nitrogen-containing compound includes a compound A1 having a fused ring, and the fused ring has an aromatic five-membered ring with one nitrogen atom.

[2] The polishing liquid for CP according to [1], in which the compound A1 has an indole ring.

[3] The polishing liquid for CP according to [1] or [2], in which an alkyl group substituted with at least one selected from the group consisting of a carboxy group and a carboxylate group is bonded to the aromatic five-membered ring.

[4] The polishing liquid for CP according to any one of [1] to [3], in which the nitrogen-containing compound includes 1H-indole-3-acetic acid.

[5] The polishing liquid for CP according to any one of [1] to [4], in which the nitrogen-containing compound includes N-acetyl-DL-tryptophan.

[6] A polishing liquid for CMP, the polishing liquid containing: abrasive grains; a nitrogen-containing compound; and water, in which the abrasive grains include cerium-based particles, and the nitrogen-containing compound includes a compound A2 having a quinoline ring and one hydroxy group bonded to the quinoline ring.

[7] A polishing liquid for CMP, the polishing liquid containing: abrasive grains; a nitrogen-containing compound; and water, in which the abrasive grains include cerium-based particles, and the nitrogen-containing compound includes a compound A3 having an aromatic ring and a hydroxy group bonded to a nitrogen atom.

[8] The polishing liquid for CP according to [7], in which the compound A3 has a benzene ring.

[9] The polishing liquid for CP according to [7] or [8], in which a hydroxyamide group is bonded to the aromatic ring.

[10] A polishing liquid for CMP, the polishing liquid containing: abrasive grains; a nitrogen-containing compound; and water, in which the abrasive grains include cerium-based particles, and the nitrogen-containing compound includes a compound A4 having a nitrogen-containing aromatic ring to which at least one selected from the group consisting of a hydroxy group and an amino group is bonded.

[11] The polishing liquid for CP according to [10], in which the compound A4 has a pyridine ring.

[12] The polishing liquid for CP according to [10] or [11], in which at least one selected from the group consisting of a carboxy group and a carboxylate group is further bonded to the nitrogen-containing aromatic ring.

[13] The polishing liquid for CP according to any one of [1] to [12], in which the cerium-based particles contain cerium oxide.

[14] The polishing liquid for CP according to any one of [1] to [13], in which pH is 3.00 to 7.00.

[15] A polishing liquid set for CMP, in which components contained in the polishing liquid for CMP according to any one of [1] to [14] are stored separately in a first liquid and a second liquid, in which the first liquid contains the abrasive grains and water, and the second liquid contains the nitrogen-containing compound and water.

[16] A polishing method including a step of polishing a surface to be polished using the polishing liquid for CMP according to any one of [1] to [14].

[17] The polishing method according to [16], in which the surface to be polished contains silicon oxide.

### Advantageous Effects of Invention

According to one aspect of the present disclosure, it is possible to provide a polishing liquid for CP capable of achieving a high polishing rate of silicon oxide at a convex portion in polishing of a patterned wafer having an uneven pattern. According to another aspect of the present disclosure, it is possible to provide a polishing liquid set for CP for obtaining such polishing liquid for CMP. According to another aspect of the present disclosure, it is possible to provide a polishing method using such polishing liquid for CMP.

### BRIEF DESCRIPTION OF DRAWINGS

FIG. 1 is a schematic cross-sectional view illustrating a process of polishing an ILD film.

### DESCRIPTION OF EMBODIMENTS

Hereinafter, embodiments of the present disclosure will be described in detail.

In the present specification, a numerical range indicated using “to” indicates a range including numerical values described before and after “to” as a minimum value and a maximum value, respectively. “A or more” of a numerical range means A and a range exceeding A. “A or less” of a numerical range means A and a range less than A. In a numerical range described stepwise in the present specification, an upper limit value or a lower limit value of a numerical range of a certain stage can be arbitrarily combined with an upper limit value or a lower limit value of a numerical range of another stage. In a numerical range described in the present specification, an upper limit value or a lower limit value of the numerical range may be replaced with a value shown in Examples. “A or B” may include either A or B, and may include both A and B. Materials exemplified in the present specification can be used alone or in combination of two or more kinds thereof unless otherwise specified. When a plurality of substances corresponding to each component are present in a composition, a content of each component in the composition means the total amount of the plurality of substances present in the composition unless otherwise specified. The term “layer” or “film” includes not only a structure having a shape formed on the entire surface but also a structure having a shape formed on a part thereof when observed in a plan view. The term “step” includes not only an independent step but also a step that cannot be clearly distinguished from other steps as long as the intended action of the step is achieved. A hydroxy group does not include an OH structure included in a carboxy group.

### <Polishing Liquid for CMP>

A polishing liquid for CMP of the present embodiment (including a first embodiment to a fourth embodiment, the same applies hereinafter) is a polishing liquid for CP (hereinafter, in some cases, simply referred to as a “polishing liquid”) containing abrasive grains, a nitrogen-containing compound, and water. The abrasive grains include cerium-based particles (particles containing a cerium-based compound). The nitrogen-containing compound of the polishing liquid of the first embodiment includes a compound A1 having a fused ring, and the fused ring has an aromatic five-membered ring with one nitrogen atom. The nitrogen-containing compound of the polishing liquid of the second embodiment includes a compound A2 having a quinoline ring and one hydroxy group bonded to the quinoline ring. The nitrogen-containing compound of the polishing liquid of the third embodiment includes a compound A3 having an aromatic ring and a hydroxy group bonded to a nitrogen atom. The nitrogen-containing compound of the polishing liquid of the fourth embodiment includes a compound A4 having a nitrogen-containing aromatic ring to which at least one selected from the group consisting of a hydroxy group and an amino group is bonded.

According to the polishing liquid of the present embodiment, it is possible to achieve a high polishing rate of silicon oxide at a convex portion in polishing of a patterned wafer having an uneven pattern constituted of a convex portion (for example, a line portion) and a concave portion (for example, a space portion), and for example, it is possible to achieve a high polishing rate of silicon oxide at the convex portion in polishing of a region of Line/Space (L/S)=30 μm/570 μm in the patterned wafer. According to the polishing liquid of the present embodiment, in an evaluation method described in Examples described later, for example, 300 nm/min or more (preferably 400 nm/min or more, 500 nm/min or more, 1000 nm/min or more, 1500 nm/min or more, 2000 nm/min or more, or the like) can be obtained as the polishing rate of silicon oxide at the convex portion in the region of L/S=30 μm/570 μm.

A factor capable of achieving the high polishing rate of silicon oxide at the convex portion in polishing of the patterned wafer is not necessarily clear, but is presumed to be as follows. However, the factor is not limited to the following contents.

That is, by using the polishing liquid containing the abrasive grains including the cerium-based particles, even if high rate polishing of silicon oxide in a blanket wafer having no uneven pattern is possible, a high polishing rate of silicon oxide at the convex portion in the patterned wafer may not be achieved, and in particular, there are cases where a specific phenomenon occurs in which a high polishing rate of silicon oxide at the convex portion cannot be achieved in polishing of a low density pattern region such as L/S=30 μm/570 μm to which an effectively high polishing pressure is likely to be applied.

On the other hand, according to the polishing liquid of the present embodiment, by using at least one nitrogen-containing compound A selected from the group consisting of the compound A1, the compound A2, the compound A3, and the compound A4, an interaction between the polishing liquid and silicon oxide at the convex portion is increased (for example, a chemical reaction between cerium-based particles in the polishing liquid and silicon oxide at the convex portion (a reaction derived from bonding of Si—O—Ce) is promoted) due to a ring structure, a functional group, or the like of the nitrogen-containing compound A, so that a high polishing rate of silicon oxide at the convex portion can be obtained, and a high polishing rate of silicon oxide at the convex portion can be achieved in polishing of the region of L/S=30 μm/570 μm in the patterned wafer.

The polishing liquid can be used to planarize a surface to be polished by polishing a patterned wafer having an uneven pattern to remove a convex portion. In this case, from the viewpoint of obtaining high planarity or the viewpoint of shortening a polishing time required for planarization, it may be required to achieve a high polishing rate ratio of silicon oxide at the convex portion in the patterned wafer having the uneven pattern with respect to silicon oxide in a blanket wafer having no uneven pattern.

According to one form of the polishing liquid of the present embodiment, a high polishing rate ratio of silicon oxide at the convex portion in the patterned wafer having the uneven pattern with respect to silicon oxide in the blanket wafer having no uneven pattern can be achieved, and for example, a high polishing rate ratio of silicon oxide at the convex portion in the region of Line/Space (L/S)=30 μm/570 μm of the patterned wafer with respect to silicon oxide in the blanket wafer having no uneven pattern can be achieved. According to one form of the polishing liquid of the present embodiment, in an evaluation method described in Examples described later, for example, 0.5 or more (preferably 1.0 or more, 5.0 or more, 10.0 or more, 30.0 or more, or the like) can be obtained as the polishing rate ratio of silicon oxide at the convex portion in the region of L/S=30 μm/570 μm of the patterned wafer with respect to silicon oxide in the blanket wafer. By obtaining a high polishing rate ratio of silicon oxide at the convex portion in the patterned wafer having the uneven pattern with respect to silicon oxide in the blanket wafer having no uneven pattern, high planarity can be realized as a characteristic that the convex portion can be selectively polished.

According to one form of the polishing liquid of the present embodiment, it is possible to achieve a high polishing rate of silicon oxide at the convex portion in polishing of the patterned wafer while achieving high-rate polishing of silicon oxide in the blanket wafer having no uneven pattern. According to one form of the polishing liquid of the present embodiment, in an evaluation method described in Examples described later, for example, 15 nm/min or more (preferably 50 nm/min or more, 100 nm/min or more, 300 nm/min or more, 500 nm/min or more, 1000 nm/min or more, or the like) can be obtained as the polishing rate of silicon oxide in the blanket wafer.

In the step of forming an element isolation region, it may be required to suppress a polishing rate of a silicon nitride film used as a stopper which is an underlayer of a silicon oxide film, and high polishing selectivity of silicon oxide with respect to silicon nitride (polishing rate of silicon oxide/polishing rate of silicon nitride) may be required. According to one form of the polishing liquid of the present embodiment, a sufficiently low polishing rate of silicon nitride can be obtained, and high polishing selectivity of silicon oxide with respect to silicon nitride can be obtained. This case is suitable for polishing when forming the element isolation region. According to one form of the polishing liquid of the present embodiment, in an evaluation method described in Examples described later, for example, 150 nm/min or less (preferably 100 nm/min or less, 50 nm/min or less, 10 nm/min or less, 5 nm/min or less, or the like) can be obtained as the polishing rate of silicon nitride in the blanket wafer.

The polishing liquid of the present embodiment can be used for CP of a semiconductor wafer material, and can be used, for example, for polishing a silicon oxide film provided on a surface of a semiconductor wafer. The polishing liquid of the present embodiment can be used in the CP step of the ILD film. According to one form of the polishing liquid of the present embodiment, it is possible to suppress aggregation of abrasive grains and occurrence of polishing scratches and obtain high planarity while obtaining a high polishing rate.

### (Abrasive Grains)

In the polishing liquid of the present embodiment, the abrasive grains include cerium-based particles (particles containing a cerium-based compound). By using the cerium-based particles as the abrasive grains, it is easy to obtain a high polishing rate of silicon oxide at the convex portion in the patterned wafer while reducing polishing scratches generated on the polished surface.

Examples of the cerium-based compound of the cerium-based particles include cerium oxide, cerium hydroxide, ammonium cerium nitrate, cerium acetate, cerium sulfate hydrate, cerium bromate, cerium bromide, cerium chloride, cerium oxalate, cerium nitrate, and cerium carbonate. The cerium-based particles may contain cerium oxide from the viewpoint of easily obtaining a high polishing rate of silicon oxide at the convex portion (such as a convex portion in the region of L/S=30 μm/570 μm: the same applies below) in the patterned wafer or the viewpoint of easily obtaining a polished surface having few polishing scratches and excellent planarity. Cerium oxide may be CeO₂ (cerium (IV) oxide, ceria), and may be Ce₂O₃ (cerium (III) oxide).

Cerium oxide particles (particles containing cerium oxide) may contain polycrystalline cerium oxide having a crystal grain boundary. Particles containing polycrystalline cerium oxide have a property that active surfaces appear one after another as the particles become fine during polishing, and a high polishing rate of silicon oxide at the convex portion in the patterned wafer can be highly maintained.

Examples of a method for producing the cerium oxide particles include a firing method; and an oxidation method using hydrogen peroxide. In the case of firing, the temperature during firing may be 350 to 900° C. When the cerium oxide particles are aggregated, the particles may be mechanically pulverized. The pulverization method may be, for example, dry pulverization using a jet mill or the like, or wet pulverization using a planetary bead mill or the like. As the jet mill, for example, a jet mill described in “Kagaku Kougaku Ronbunshu (Collection of Chemical Engineering Papers)”, Vol. 6, No. 5, (1980), page 527 to 532 can be used.

A zeta potential (surface potential) of the abrasive grains in the polishing liquid may be positive (a zeta potential may exceed 0 mV) from the viewpoint of easily obtaining a high polishing rate of silicon oxide at the convex portion in the patterned wafer. The zeta potential of the abrasive grains can be measured using, for example, a dynamic light scattering zeta potential measuring device (for example, trade name: DelsaNano C manufactured by Beckman Coulter Inc.). The zeta potential of the abrasive grains can be adjusted using an additive. For example, by bringing an acid component (for example, acetic acid) into contact with the abrasive grains, abrasive grains having a positive zeta potential can be obtained.

The average particle diameter of the abrasive grains may be 50 nm or more, 70 nm or more, 80 nm or more, 100 nm or more, more than 100 nm, 105 nm or more, 110 nm or more, 115 nm or more, 120 nm or more, 125 nm or more, 130 nm or more, 135 nm or more, or 140 nm or more, from the viewpoint of easily obtaining a high polishing rate of silicon oxide at the convex portion in the patterned wafer. The average particle diameter of the abrasive grains may be 500 nm or less, 400 nm or less, 300 nm or less, 200 nm or less, 180 nm or less, 150 nm or less, or 140 nm or less, from the viewpoint of easily suppressing occurrence of polishing scratches. From these viewpoints, the average particle diameter of the abrasive grains may be 50 to 500 nm, 50 to 200 nm, 50 to 150 nm, 70 to 500 nm, 70 to 200 nm, 70 to 150 nm, 100 to 500 nm, 100 to 200 nm, or 100 to 150 nm.

The “average particle diameter of the abrasive grains” means a median value of a volume distribution obtained by measuring a sample in which the abrasive grains are dispersed with a particle diameter distribution measuring device (for example, a laser diffraction/scattering type particle diameter distribution measuring device), and can be measured using trade name: Microtrac MT3300EXII manufactured by MicrotracBEL Corp. or the like. For example, a sample is prepared by dispersing the abrasive grains in water so as to be adjusted to the content of the abrasive grains having scattering intensity in a range suitable for measurement, this sample is set in a measuring device, and the average particle diameter is measured. In the case of measuring the particle diameter of the abrasive grains in the polishing liquid, a sample is prepared by adjusting the content of the abrasive grains in the polishing liquid so as to obtain the content of the abrasive grains having scattering intensity in a range suitable for measurement, and measurement can be performed by the same method using this sample. By adjusting the average particle diameter of the abrasive grains, a high polishing rate and low scratch characteristics of silicon oxide according to the particle diameter of the abrasive grains can be efficiently obtained.

The content of the abrasive grains may be in the following range based on the total mass of the polishing liquid from the viewpoint of easily obtaining a high polishing rate of silicon oxide at the convex portion in the patterned wafer. The content of the abrasive grains maybe 0.01% by mass or more, 0.05% by mass or more, 0.10% by mass or more, 0.20% by mass or more, 0.30% by mass or more, 0.40% by mass or more, 0.50% by mass or more, 0.60% by mass or more, 0.70% by mass or more, 0.80% by mass or more, 0.90% by mass or more, or 1.0% by mass or more. The content of the abrasive grains may be 20% by mass or less, 15% by mass or less, 12% by mass or less, 10% by mass or less, 8.0% by mass or less, 6.0% by mass or less, 5.0% by mass or less, 4.0% by mass or less, 3.0% by mass or less, 2.0% by mass or less, 1.5% by mass or less, or 1.0% by mass or less, from the viewpoint of easily achieving excellent dispersion stability of the abrasive grains. From these viewpoints, the content of the abrasive grains may be 0.01 to 20% by mass, 0.01 to 10% by mass, 0.01 to 5.0% by mass, 0.10 to 20% by mass, 0.10 to 10% by mass, 0.10 to 5.0% by mass, 0.50 to 20% by mass, 0.50 to 10% by mass, or 0.50 to 5.0% by mass.

### (Nitrogen-Containing Compound)

The nitrogen-containing compound of the polishing liquid of the present embodiment includes at least one nitrogen-containing compound A selected from the group consisting of a compound A1, a compound A2, a compound A3, and a compound A4. The nitrogen-containing compound of the polishing liquid of the present embodiment may include the nitrogen-containing compound A and a nitrogen-containing compound that does not correspond to the nitrogen-containing compound A.

The nitrogen-containing compound of the polishing liquid of the first embodiment includes the compound A1 having a fused ring C1, and the fused ring C1 has an aromatic five-membered ring with one nitrogen atom (hereinafter referred to as “five-membered ring C11”). In the five-membered ring C11, the number of nitrogen atoms (nitrogen atoms constituting the five-membered ring C11) is one. Examples of the five-membered ring C11 include a pyrrole ring, an oxazole ring, an isoxazole ring, a thiazole ring, and an isothiazole ring. The fused ring C1 may have the pyrrole ring as the five-membered ring C11 from the viewpoint of easily obtaining a high polishing rate of silicon oxide at the convex portion in the patterned wafer.

The fused ring C1 has the five-membered ring C11 and other ring C12. The ring C12 may be an aromatic ring, may be a non-aromatic ring (alicyclic ring or the like), may be a heterocyclic ring, and may be a non-heterocyclic ring. The compound A1 may have a fused ring having the five-membered ring C11 and the aromatic ring, may have a fused ring having the five-membered ring C11 and the non-heterocyclic ring, and may have a fused ring having the five-membered ring C11 and a benzene ring, from the viewpoint of easily obtaining a high polishing rate of silicon oxide at the convex portion in the patterned wafer. The fused ring C1 may be a fused ring composed of the five-membered ring C11 and other ring C12 from the viewpoint of easily obtaining a high polishing rate of silicon oxide at the convex portion in the patterned wafer.

The compound A1 may have an indole ring as the fused ring C1 from the viewpoint of easily obtaining a high polishing rate of silicon oxide at the convex portion in the patterned wafer. The compound A1 may have a ring other than the fused ring C1, but may not have a ring other than the fused ring C1 from the viewpoint of easily obtaining a high polishing rate of silicon oxide at the convex portion in the patterned wafer.

In addition to the nitrogen atom of the five-membered ring C11, the compound A1 may have a nitrogen atom that does not constitute the five-membered ring C11, and may have a nitrogen atom that does not constitute a ring. The number of nitrogen atoms in the compound A1 may be one or two from the viewpoint of easily obtaining a high polishing rate of silicon oxide at the convex portion in the patterned wafer.

A substituent may be bonded to the fused ring C1. The substituent may be bonded to the five-membered ring C11 and may be bonded to the ring C12. Examples of the substituent include a substituted or unsubstituted alkyl group, a hydroxy group, a carboxy group, a carboxylate group, an aldehyde group, an alkoxy group, an ester group, a substituted or unsubstituted amino group, an amide group (excluding a hydroxyamide group), a hydroxyamide group, a nitro group, a cyano group, a mercapto group, and a halogeno group (a fluoro group, a chloro group, a bromo group, an iodo group, and the like). The number of carbon atoms of the alkyl group (not including the number of carbon atoms of the substituent) may be one, two, or three from the viewpoint of easily obtaining a high polishing rate of silicon oxide at the convex portion in the patterned wafer, the viewpoint of easily achieving a high polishing rate ratio of silicon oxide at the convex portion in the patterned wafer with respect to silicon oxide in the blanket wafer, or the viewpoint of easily obtaining high polishing selectivity of silicon oxide with respect to silicon nitride, and may be one or two from the viewpoint of easily achieving excellent dispersion stability of the abrasive grains.

From the viewpoint of easily obtaining a high polishing rate of silicon oxide at the convex portion in the patterned wafer, the viewpoint of easily achieving a high polishing rate ratio of silicon oxide at the convex portion in the patterned wafer with respect to silicon oxide in the blanket wafer, or the viewpoint of easily obtaining a high polishing selectivity of silicon oxide with respect to silicon nitride, at least one selected from the group consisting of a substituted or unsubstituted alkyl group, a hydroxy group, a carboxy group, a carboxylate group, and an alkoxy group may be bonded to the fused ring C1, and an alkyl group in which at least one selected from the group consisting of a carboxy group, a carboxylate group, an alkoxy group, an ester group, and an amino group (unsubstituted amino group, acetylamino group, and the like) is substituted may be bonded to the fused ring C1.

From the viewpoint of easily obtaining a high polishing rate of silicon oxide at the convex portion in the patterned wafer, the viewpoint of easily achieving a high polishing rate ratio of silicon oxide at the convex portion in the patterned wafer with respect to silicon oxide in the blanket wafer, or the viewpoint of easily obtaining a high polishing selectivity of silicon oxide with respect to silicon nitride, at least one selected from the group consisting of a substituted or unsubstituted alkyl group, a carboxy group, and a carboxylate group may be bonded to the five-membered ring C11, an alkyl group substituted with at least one selected from the group consisting of a carboxy group, a carboxylate group, an alkoxy group, an ester group, and an amino group (unsubstituted amino group, acetylamino group, and the like) may be bonded to the five-membered ring C11, and an alkyl group substituted with at least one selected from the group consisting of a carboxy group and a carboxylate group may be bonded to the five-membered ring C11. From the viewpoint of easily achieving excellent dispersion stability of the abrasive grains, an alkyl group substituted with at least one selected from the group consisting of a carboxy group, a carboxylate group, an ester group, and an amino group (unsubstituted amino group, acetylamino group, and the like) may be bonded to the five-membered ring C11.

The substituent bonded to the five-membered ring C11 may be bonded to an atom (for example, a carbon atom) at the 3-position with respect to a nitrogen atom in the five-membered ring C11 (for example, a pyrrole ring) from the viewpoint of easily obtaining a high polishing rate of silicon oxide at the convex portion in the patterned wafer. At least one selected from the group consisting of a hydroxy group and an alkoxy group may be bonded to the ring C12 from the viewpoint of easily obtaining a high polishing rate of silicon oxide at the convex portion in the patterned wafer. The ring C12 may be unsubstituted from the viewpoint of easily obtaining a high polishing rate of silicon oxide at the convex portion in the patterned wafer.

The nitrogen-containing compound of the polishing liquid of the first embodiment may include, as the compound A1, at least one selected from the group consisting of 1H-indole-3-carboxylic acid, 1H-indole-3-acetic acid, 1H-indole-3-propionic acid, 1H-indole-3-methyl acetate, 3-methoxymethylindole, N-acetyl-DL-tryptophan, 5-hydroxy-L-tryptophan, 5-hydroxyindole-3-acetic acid, and 5-methoxyindole-3-acetic acid, may include 1H-indole-3-acetic acid, and may include N-acetyl-DL-tryptophan, from the viewpoint of easily obtaining a high polishing rate of silicon oxide at the convex portion in the patterned wafer.

The nitrogen-containing compound of the polishing liquid of the second embodiment includes a compound A2 having a quinoline ring and one hydroxy group bonded to the quinoline ring. The compound A2 has one hydroxy group directly bonded to the quinoline ring. In the compound A2, the number of hydroxy groups bonded to the quinoline ring is one. The compound A2 may have a hydroxy group not bonded to the quinoline ring, but may not have a hydroxy group not bonded to the quinoline ring from the viewpoint of easily obtaining a high polishing rate of silicon oxide at the convex portion in the patterned wafer.

The hydroxy group bonded to the quinoline ring may be bonded to a carbon atom at the 8-position with respect to the nitrogen atom in the quinoline ring from the viewpoint of easily obtaining a high polishing rate of silicon oxide at the convex portion in the patterned wafer.

The number of nitrogen atoms in the compound A2 may be one from the viewpoint of easily obtaining a high polishing rate of silicon oxide at the convex portion in the patterned wafer. The compound A2 may have a nitrogen atom other than the nitrogen atom constituting the quinoline ring, but may not have a nitrogen atom other than the nitrogen atom constituting the quinoline ring from the viewpoint of easily obtaining a high polishing rate of silicon oxide at the convex portion in the patterned wafer.

A substituent other than a hydroxy group may be bonded to the quinoline ring. Examples of the substituent include a substituted or unsubstituted alkyl group, a carboxy group, a carboxylate group, an aldehyde group, an alkoxy group, an ester group, a substituted or unsubstituted amino group, an amide group (excluding a hydroxyamide group), a hydroxyamide group, a nitro group, a cyano group, a mercapto group, and a halogeno group (a fluoro group, a chloro group, a bromo group, an iodo group, and the like). A substituent other than a hydroxy group may not bond to the quinoline ring from the viewpoint of easily obtaining a high polishing rate of silicon oxide at the convex portion in the patterned wafer.

The nitrogen-containing compound of the polishing liquid of the second embodiment may include 8-hydroxyquinoline as the compound A2 from the viewpoint of easily obtaining a high polishing rate of silicon oxide at the convex portion in the patterned wafer.

The nitrogen-containing compound of the polishing liquid of the third embodiment includes a compound A3 having an aromatic ring and a hydroxy group bonded to a nitrogen atom. The compound A3 has a hydroxy group directly bonded to a nitrogen atom.

The nitrogen atom to which the hydroxy group is bonded may be directly bonded to the aromatic ring, but may not be directly bonded to the aromatic ring from the viewpoint of easily obtaining a high polishing rate of silicon oxide at the convex portion in the patterned wafer. The nitrogen atom to which the hydroxy group is bonded may be a nitrogen atom constituting a ring, but may be a nitrogen atom not constituting a ring from the viewpoint of easily obtaining a high polishing rate of silicon oxide at the convex portion in the patterned wafer.

The compound A3 may have an aromatic ring constituting a fused ring, but may have a monocyclic aromatic ring (an aromatic ring not constituting a fused ring) from the viewpoint of easily obtaining a high polishing rate of silicon oxide at the convex portion in the patterned wafer. The compound A3 may have a heterocyclic ring as an aromatic ring, but may have a non-heterocyclic ring and may have a benzene ring from the viewpoint of easily obtaining a high polishing rate of silicon oxide at the convex portion in the patterned wafer.

The number of aromatic rings or the number of benzene rings in the compound A3 may be one from the viewpoint of easily obtaining a high polishing rate of silicon oxide at the convex portion in the patterned wafer. For example, when the compound A3 has a fused ring constituted of two aromatic rings, the number of aromatic rings is two (the same applies to the number of benzene rings). The number of nitrogen atoms in the compound A3 may be one from the viewpoint of easily obtaining a high polishing rate of silicon oxide at the convex portion in the patterned wafer.

The number of hydroxy groups in the compound A3 may be one or two from the viewpoint of easily obtaining a high polishing rate of silicon oxide at the convex portion in the patterned wafer, may be one from the viewpoint of easily obtaining a further high polishing rate of silicon oxide at the convex portion in the patterned wafer, and may be two from the viewpoint of easily achieving a high polishing rate ratio of silicon oxide at the convex portion in the patterned wafer with respect to silicon oxide in the blanket wafer or the viewpoint of easily obtaining a high polishing selectivity of silicon oxide with respect to silicon nitride. In the compound A3, the number of hydroxy groups bonded to a nitrogen atom may be one from the viewpoint of easily obtaining a high polishing rate of silicon oxide at the convex portion in the patterned wafer. The compound A3 may not have a hydroxy group not bonded to a nitrogen atom from the viewpoint of easily obtaining a high polishing rate of silicon oxide at the convex portion in the patterned wafer. From the viewpoint of easily achieving a high polishing rate ratio of silicon oxide at the convex portion in the patterned wafer with respect to silicon oxide in the blanket wafer or the viewpoint of easily obtaining a high polishing selectivity of silicon oxide with respect to silicon nitride, the compound A3 may have a hydroxy group (for example, a hydroxy group bonded to an aromatic ring) not bonded to a nitrogen atom in addition to a hydroxy group bonded to a nitrogen atom.

A substituent may be bonded to the aromatic ring. Examples of the substituent include a substituted or unsubstituted alkyl group, a hydroxy group, a carboxy group, a carboxylate group, an aldehyde group, an alkoxy group, an ester group, a substituted or unsubstituted amino group, an amide group (excluding a hydroxyamide group), a hydroxyamide group, a nitro group, a cyano group, a mercapto group, and a halogeno group (a fluoro group, a chloro group, a bromo group, an iodo group, and the like). The hydroxyamide group may be bonded to the aromatic ring from the viewpoint of easily obtaining a high polishing rate of silicon oxide at the convex portion in the patterned wafer. From the viewpoint of easily achieving a high polishing rate ratio of silicon oxide at the convex portion in the patterned wafer with respect to silicon oxide in the blanket wafer or the viewpoint of easily obtaining a high polishing selectivity of silicon oxide with respect to silicon nitride, a hydroxy group may be bonded to the aromatic ring.

As the compound A3, the nitrogen-containing compound of the polishing liquid of the third embodiment may include at least one selected from the group consisting of benzohydroxamic acid and salicylaldoxime from the viewpoint of easily obtaining a high polishing rate of silicon oxide at the convex portion in the patterned wafer, may include benzohydroxamic acid from the viewpoint of easily obtaining a further high polishing rate of silicon oxide at the convex portion in the patterned wafer, and may include salicylaldoxime from the viewpoint of easily obtaining a high polishing rate ratio of silicon oxide at the convex portion in the patterned wafer with respect to silicon oxide in the blanket wafer or the viewpoint of easily obtaining high polishing selectivity of silicon oxide with respect to silicon nitride.

The nitrogen-containing compound of the polishing liquid of the fourth embodiment includes a compound A4 having a nitrogen-containing aromatic ring C4 to which at least one selected from the group consisting of a hydroxy group and an amino group is bonded. The compound A4 has at least one selected from the group consisting of a hydroxy group and an amino group as a substituent directly bonded to the nitrogen-containing aromatic ring C4. In a compound having a fused ring constituted of a nitrogen-containing aromatic ring X1 and a ring X2 not corresponding to a nitrogen-containing aromatic ring, when the hydroxy group and the amino group are not bonded to the nitrogen-containing aromatic ring X1 and at least one selected from the group consisting of the hydroxy group and the amino group is bonded to the ring X2, such a compound does not correspond to the compound A4.

At least one selected from the group consisting of the hydroxy group and the amino group may be bonded to at least one selected from the group consisting of an atom (for example, a carbon atom) at the 3-position and an atom (for example, a carbon atom) at the 5-position with respect to a nitrogen atom in the nitrogen-containing aromatic ring C4 from the viewpoint of easily obtaining a high polishing rate of silicon oxide at the convex portion in the patterned wafer, may be bonded to the atom (for example, the carbon atom) at the 3-position with respect to a nitrogen atom in the nitrogen-containing aromatic ring C4 from the viewpoint of easily achieving a high polishing rate ratio of silicon oxide at the convex portion in the patterned wafer with respect to silicon oxide in the blanket wafer, and may be bonded to the atom (for example, the carbon atom) at the 5-position with respect to a nitrogen atom in the nitrogen-containing aromatic ring C4 from the viewpoint of easily obtaining a further high polishing rate of silicon oxide at the convex portion in the patterned wafer or the viewpoint of easily obtaining high polishing selectivity of silicon oxide with respect to silicon nitride.

Examples of the nitrogen-containing aromatic ring C4 include six-membered rings such as a pyridine ring, a pyridazine ring, a pyrimidine ring, and a pyrazine ring; and five-membered rings such as a pyrrole ring, a pyrazole ring, an imidazole ring, a triazole ring, and a tetrazole ring. The compound A4 may have a six-membered ring and may have a pyridine ring as the nitrogen-containing aromatic ring C4 from the viewpoint of easily obtaining a high polishing rate of silicon oxide at the convex portion in the patterned wafer. The compound A4 may have a nitrogen-containing aromatic ring constituting a fused ring as the nitrogen-containing aromatic ring C4, but may have a monocyclic nitrogen-containing aromatic ring (nitrogen-containing aromatic ring not constituting a fused ring) from the viewpoint of easily obtaining a high polishing rate of silicon oxide at the convex portion in the patterned wafer. The number of the nitrogen-containing aromatic rings C4 in the compound A4 may be one from the viewpoint of easily obtaining a high polishing rate of silicon oxide at the convex portion in the patterned wafer.

The compound A4 may have a hydroxy group not bonded to a nitrogen-containing aromatic ring and may have an amino group not bonded to the nitrogen-containing aromatic ring, but from the viewpoint of easily obtaining a high polishing rate of silicon oxide at the convex portion in the patterned wafer, the compound A4 may not have a hydroxy group not bonded to the nitrogen-containing aromatic ring, may not have the amino group not bonded to the nitrogen-containing aromatic ring, and may not have a hydroxy group and the amino group which are not bonded to the nitrogen-containing aromatic ring.

The number of hydroxy groups (total of a hydroxy group bonded to the nitrogen-containing aromatic ring and a hydroxy group not bonded to the nitrogen-containing aromatic ring) in the compound A4 may be one from the viewpoint of easily obtaining a high polishing rate of silicon oxide at the convex portion in the patterned wafer. In the compound A4, the number of hydroxy groups bonded to the nitrogen-containing aromatic ring may be one from the viewpoint of easily obtaining a high polishing rate of silicon oxide at the convex portion in the patterned wafer.

The number of amino groups (total of the amino group bonded to the nitrogen-containing aromatic ring and the amino group not bonded to the nitrogen-containing aromatic ring) in the compound A4 may be one from the viewpoint of easily obtaining a high polishing rate of silicon oxide at the convex portion in the patterned wafer. In the compound A4, the number of amino groups bonded to the nitrogen-containing aromatic ring may be one from the viewpoint of easily obtaining a high polishing rate of silicon oxide at the convex portion in the patterned wafer.

The number of nitrogen atoms in the compound A4 may be one or two from the viewpoint of easily obtaining a high polishing rate of silicon oxide at the convex portion in the patterned wafer, may be one from the viewpoint of easily achieving a high polishing rate ratio of silicon oxide at the convex portion in the patterned wafer with respect to silicon oxide in the blanket wafer or the viewpoint of easily obtaining a high polishing selectivity of silicon oxide with respect to silicon nitride, and may be two from the viewpoint of easily obtaining a further high polishing rate of silicon oxide at the convex portion in the patterned wafer. The number of nitrogen atoms (nitrogen atoms constituting the nitrogen aromatic ring) in the nitrogen-containing aromatic ring C4 may be one from the viewpoint of easily obtaining a high polishing rate of silicon oxide at the convex portion in the patterned wafer.

A substituent other than the hydroxy group and the amino group may be bonded to the nitrogen-containing aromatic ring C4. Examples of the substituent include a substituted or unsubstituted alkyl group, a carboxy group, a carboxylate group, an aldehyde group, an alkoxy group, an ester group, an amide group (excluding a hydroxyamide group), a hydroxyamide group, a nitro group, a cyano group, a mercapto group, and a halogeno group (a fluoro group, a chloro group, a bromo group, an iodo group, and the like). From the viewpoint of easily obtaining a high polishing rate of silicon oxide at the convex portion in the patterned wafer, at least one selected from the group consisting of a carboxy group and a carboxylate group may be bonded to the nitrogen-containing aromatic ring C4, and at least one selected from the group consisting of a carboxy group and a carboxylate group may be bonded to an atom (for example, a carbon atom) at the 2-position with respect to a nitrogen atom in the nitrogen-containing aromatic ring C4.

The nitrogen-containing compound of the polishing liquid of the fourth embodiment may include, as the compound A4, at least one selected from the group consisting of 3-hydroxy-2-pyridinecarboxylic acid, 5-hydroxy-2-pyridinecarboxylic acid, and 5-amino-2-pyridinecarboxylic acid, and may include 5-hydroxy-2-pyridinecarboxylic acid, from the viewpoint of easily obtaining a high polishing rate of silicon oxide at the convex portion in the patterned wafer.

The content of the nitrogen-containing compound A, the content of the compound A1, the content of the compound A2, the content of the compound A3, or the content of the compound A4 may be 50% by mass or more, 70% by mass or more, 90% by mass or more, 95% by mass or more, 97% by mass or more, 98% by mass or more, or 99% by mass or more based on the entire nitrogen-containing compound (the entire nitrogen-containing compound contained in the polishing liquid) from the viewpoint of easily obtaining a high polishing rate of silicon oxide at the convex portion in the patterned wafer. The nitrogen-containing compound contained in the polishing liquid may be a form substantially composed of the nitrogen-containing compound A, the compound A1, the compound A2, the compound A3, or the compound A4 (a form in which substantially 100% by mass of the nitrogen-containing compound contained in the polishing liquid is the nitrogen-containing compound A, the compound A1, the compound A2, the compound A3, or the compound A4).

As the content of the nitrogen-containing compound A, the content of the compound A1, the content of the compound A2, the content of the compound A3, or the content of the compound A4, a content A may be in the following range based on the total mass of the polishing liquid from the viewpoint of easily obtaining a high polishing rate of silicon oxide at the convex portion in the patterned wafer. The content A may be 0.001% by mass or more, 0.005% by mass or more, 0.01% by mass or more, 0.03% by mass or more, 0.05% by mass or more, 0.08% by mass or more, or 0.10% by mass or more. The content A may be 10% by mass or less, 8.0% by mass or less, 5.0% by mass or less, 3.0% by mass or less, 1.0% by mass or less, 0.80% by mass or less, 0.50% by mass or less, 0.30% by mass or less, 0.20% by mass or less, or 0.10% by mass or less. From these viewpoints, the content A may be 0.001 to 10% by mass, 0.001 to 1.0% by mass, 0.001 to 0.50% by mass, 0.01 to 10% by mass, 0.01 to 1.0% by mass, 0.01 to 0.50% by mass, 0.05 to 10% by mass, 0.05 to 1.0% by mass, or 0.05 to 0.50% by mass.

As a mass ratio of the content of the nitrogen-containing compound A with respect to the content of the abrasive grains (nitrogen-containing compound A/abrasive grains), a mass ratio of the content of the compound A1 with respect to the content of the abrasive grains (compound A1/abrasive grains), a mass ratio of the content of the compound A2 with respect to the content of the abrasive grains (compound A2/abrasive grains), a mass ratio of the content of the compound A3 with respect to the content of the abrasive grains (compound A3/abrasive grains), or a mass ratio of the content of the compound A4 with respect to the content of the abrasive grains (compound A4/abrasive grains), a mass ratio B may be in the following range from the viewpoint of easily obtaining a high polishing rate of silicon oxide at the convex portion in the patterned wafer. The mass ratio B may be 0.001 or more, 0.005 or more, 0.01 or more, 0.03 or more, 0.05 or more, 0.08 or more, or 0.10 or more. The mass ratio B may be 10 or less, 8.0 or less, 5.0 or less, 3.0 or less, 1.0 or less, 0.80 or less, 0.50 or less, 0.30 or less, 0.20 or less, or 0.10 or less. From these viewpoints, the mass ratio B may be 0.001 to 10, 0.001 to 1.0, 0.001 to 0.50, 0.01 to 10, 0.01 to 1.0, 0.01 to 0.50, 0.05 to 10, 0.05 to 1.0, or 0.05 to 0.50.

The polishing liquid of the present embodiment may contain a nonionic polymer. Examples of the nonionic polymer include ether type surfactants such as polyglycerin, polyglycerin fatty acid ester, polyglycerin derivative, polyoxyethylene distyrenated phenyl ether, polyoxyethylene sorbitan monolaurate, polyoxyethylene lauryl ether, polyoxypropylene polyoxyethylene alkyl ether, polyoxyethylene alkyl allyl ether, polyoxyethylene polyoxypropylene ether derivative, polyoxypropylene glyceryl ether, polyethylene glycol, methoxy polyethylene glycol, and oxyethylene adduct of acetylene diol; ester type surfactants such as sorbitan fatty acid ester and glycerol borate fatty acid ester; aminoether type surfactants such as polyoxyethylene alkylamines; ether ester type surfactant such as polyoxyethylene glycerol borate fatty acid ester and polyoxyethylene alkyl ester; alkanolamide type surfactants such as fatty acid alkanolamide and polyoxyethylene fatty acid alkanolamide; polyvinylpyrrolidone; nonionic polyacrylamide; and nonionic polydimethylacrylamide. The nonionic polymer may include at least one selected from the group consisting of an ether type surfactant, an ester type surfactant, an amino ether type surfactant, an ether ester type surfactant, an alkanolamide type surfactant, polyvinylpyrrolidone, nonionic polyacrylamide, and nonionic polydimethylacrylamide, and may include polyglycerin, from the viewpoint of easily obtaining a high polishing rate of silicon oxide at the convex portion in the patterned wafer.

The content of the nonionic polymer may be in the following range based on the total mass of the polishing liquid from the viewpoint of easily obtaining a high polishing rate of silicon oxide at the convex portion in the patterned wafer. The content of the nonionic polymer may be 0.01% by mass or more, 0.03% by mass or more, 0.05% by mass or more, 0.08% by mass or more, 0.10% by mass or more, 0.15% by mass or more, or 0.20% by mass or more. The content of the nonionic polymer may be 5.00% by mass or less, 3.00% by mass or less, 1.00% by mass or less, 0.80% by mass or less, 0.50% by mass or less, 0.30% by mass or less, or 0.20% by mass or less. From these viewpoints, the content of the nonionic polymer may be 0.01 to 5.00% by mass, 0.01 to 1.00% by mass, 0.01 to 0.50% by mass, 0.05 to 5.00% by mass, 0.05 to 1.00% by mass, 0.05 to 0.50% by mass, 0.10 to 5.00% by mass, 0.10 to 1.00% by mass, or 0.10 to 0.50% by mass.

The polishing liquid of the present embodiment may contain an acyclic alcohol. The acyclic alcohol is an alcohol having no cyclic structure. By using the acyclic alcohol, dispersion stability of the abrasive grains in the polishing liquid is easily improved.

Examples of the acyclic alcohol include methanol, ethanol, n-propanol, isopropanol, n-butanol, isobutanol, 1,3-butanediol, 1,4-butanediol, 2-ethylhexanol, 3-methoxy-3-methyl-1-butanol, butyl cellosolve (2-butoxyethanol), butyl carbitol (diethylene glycol mono-n-butyl ether), dipropylene glycol monomethyl ether, ethyl cellosolve (2-ethoxyethanol), methyl carbitol (diethylene glycol monomethyl ether), ethyl carbitol (diethylene glycol monoethyl ether), 1-methoxy-2 propanol, 1-butoxy-2-propanol, and tert-butyl cellosolve. The acyclic alcohol may include 3-methoxy-3-methyl-1-butanol from the viewpoint of easily obtaining a high polishing rate of silicon oxide at the convex portion in the patterned wafer or the viewpoint of easily achieving excellent dispersion stability of the abrasive grains.

The content of the acyclic alcohol may be in the following range based on the total mass of the polishing liquid from the viewpoint of easily obtaining a high polishing rate of silicon oxide at the convex portion in the patterned wafer or the viewpoint of easily achieving excellent dispersion stability of the abrasive grains. The content of the acyclic alcohol may be 0.01% by mass or more, 0.05% by mass or more, 0.10% by mass or more, 0.50% by mass or more, 1.0% by mass or more, 1.2% by mass or more, 1.4% by mass or more, 1.5% by mass or more, 2.0% by mass or more, 3.0% by mass or more, 5.0% by mass or more, or 8.0% by mass or more. The content of the acyclic alcohol may be 50% by mass or less, 30% by mass or less, 20% by mass or less, 10% by mass or less, 9.0% by mass or less, 8.0% by mass or less, 5.0% by mass or less, 3.0% by mass or less, 2.0% by mass or less, 1.5% by mass or less, or 1.4% by mass or less. From these viewpoints, the content of the acyclic alcohol may be 0.01 to 50% by mass, 0.01 to 10% by mass, 0.01 to 5.0% by mass, 0.10 to 50% by mass, 0.10 to 10% by mass, 0.10 to 5.0% by mass, 1.0 to 50% by mass, 1.0 to 10% by mass, 1.0 to 5.0% by mass, 5.0 to 50% by mass, or 5.0 to 10% by mass.

### (Other Additives)

The polishing liquid of the present embodiment may contain other component (a component not corresponding to the above-described components) according to desired characteristics. Examples of such component include a cationic compound; and a pH adjusting agent described later.

The polishing liquid of the present embodiment may contain a compound a having a molecular weight of 100000 or less and having four or more hydroxy groups, and may not contain the compound a. The content of the compound a may be 0.01% by mass or less, less than 0.01% by mass, 0.001% by mass or less, 0.0001% by mass or less, or substantially 0% by mass based on the total mass of the polishing liquid. The polishing liquid of the present embodiment may contain a compound b having four or more amino groups, and may not contain the compound b. The content of the compound b may be 0.001% by mass or less, less than 0.001% by mass, 0.00010% by mass or less, 0.000010% by mass or less, or substantially 0% by mass based on the total mass of the polishing liquid. The mass ratio of the content of the compound a with respect to the content of the compound b (compound a/compound b) may be 0.10 or less or less than 0.10.

### (Water)

The water is not particularly limited, but may include at least one selected from the group consisting of deionized water, ion-exchanged water, and ultrapure water.

(pH)

The pH of the polishing liquid of the present embodiment may be in the following range from the viewpoint of easily obtaining a high polishing rate of silicon oxide at the convex portion in the patterned wafer or the viewpoint of easily achieving excellent dispersion stability of the abrasive grains. The pH may be 12.00 or less, 11.00 or less, 10.50 or less, 10.00 or less, less than 10.00, 9.50 or less, 9.00 or less, less than 9.00, 8.50 or less, 8.00 or less, less than 8.00, 7.50 or less, 7.00 or less, less than 7.00, 6.50 or less, 6.00 or less, less than 6.00, 5.50 or less, 5.00 or less, less than 5.00, 4.50 or less, 4.30 or less, 4.20 or less, 4.00 or less, less than 4.00, 3.70 or less, 3.65 or less, 3.60 or less, 3.50 or less, or 3.30 or less. The pH may be 2.00 or more, more than 2.00, 2.50 or more, 3.00 or more, more than 3.00, 3.30 or more, 3.50 or more, 3.60 or more, 3.65 or more, 3.70 or more, 4.00 or more, more than 4.00, 4.20 or more, 4.30 or more, 4.50 or more, 5.00 or more, more than 5.00, 5.50 or more, 6.00 or more, or more than 6.00. From these viewpoints, the pH may be 2.00 to 12.00, 2.00 to 7.00, 2.00 to 5.00, 3.00 to 12.00, 3.00 to 7.00, 3.00 to 5.00, 4.00 to 12.00, 4.00 to 7.00, or 4.00 to 5.00. The pH can be measured by a method described in Examples.

Since the pH can vary depending on the type of compound used as an additive, a pH adjusting agent may be used to adjust the pH to the above range. The pH adjusting agent is not particularly limited, and examples thereof include acids such as nitric acid, sulfuric acid, hydrochloric acid, phosphoric acid, and boric acid; and bases such as sodium hydroxide, ammonia (for example, ammonia water), potassium hydroxide, and calcium hydroxide. The above-described components such as a nitrogen-containing compound may be used for pH adjustment. From the viewpoint of improving productivity, the polishing liquid may be prepared without using the pH adjusting agent, and this polishing liquid may be directly applied to CMP.

### <Preparation Method and Use Method of Polishing Liquid>

The polishing liquid of the present embodiment can be classified into (a) normal type, (b) concentration type, and (c) multiple liquid type (for example, two liquid type, a polishing liquid set for CMP), and a preparation method and a use method differ depending on the type. The (a) normal type is a polishing liquid that can be used as it is without being subjected to a pretreatment such as dilution at the time of polishing. The (b) concentration type is a polishing liquid in which the components are concentrated as compared with the (a) normal type considering convenience in storage and transportation. The (c) multiple liquid type is a polishing liquid in which the components are divided into a plurality of liquids (for example, the components are divided into a first liquid containing a certain component and a second liquid containing other component) at the time of storage or transportation, and these liquids are mixed and used at the time of use.

The (a) normal type can be obtained by dissolving or dispersing abrasive grains and additives in water which is a main dispersing medium. The polishing liquid can be prepared using, for example, a stirrer, a homogenizer, an ultrasonic disperser, a wet ball mill, or the like. A treatment of micronizing the abrasive grains may be performed in the process of preparing the polishing liquid so that the average particle diameter of the abrasive grains falls within a desired range. The treatment of micronizing the abrasive grains can be performed by a sedimentation classification method or a method using a high-pressure homogenizer. The sedimentation classification method is a method including a step of forcibly settling a slurry containing abrasive grains using a centrifuge and a step of taking out only a supernatant liquid. On the other hand, the method using a high-pressure homogenizer is a method in which abrasive grains in a dispersion medium collide with each other at high pressure.

The (b) concentration type is diluted with water immediately before use so that the components have a desired content. After the dilution, stirring may be performed for an arbitrary time until liquid characteristics (pH, particle diameter of abrasive grains, or the like) and polishing characteristics (polishing rate of silicon oxide, polishing selection ratio of silicon oxide with respect to silicon nitride, or the like) equivalent to those of the (a) normal type are obtained. In such (b) concentration type, since the volume decreases according to a degree of concentration, costs for storage and transportation can be reduced.

The concentration ratio may be 1.5 times or more, 2 times or more, 3 times or more, or 5 times or more. When the concentration ratio is 1.5 times or more, advantages regarding storage and transportation tend to be easily obtained as compared with a case of the concentration ratio of less than 1.5 times. The concentration ratio may be 40 times or less, 20 times or less, or 15 times or less. When the concentration ratio is 40 times or less, the aggregation of the abrasive grains tends to be easily suppressed as compared with a case of the concentration ratio exceeding 40 times.

The (c) multiple liquid type has an advantage in that aggregation of abrasive grains and the like can be avoided by appropriately dividing each liquid (first liquid, second liquid, and the like) as compared with the (b) concentration type. The components contained in each liquid are arbitrary. The (c) multiple liquid type (polishing liquid set for CP) is a polishing liquid set for obtaining a polishing liquid by mixing the first liquid (slurry) with the second liquid (additive liquid). For example, in the (c) multiple liquid type, components of the polishing liquid for CMP are stored separately in the first liquid and the second liquid, the first liquid contains abrasive grains and water, and the second liquid contains a nitrogen-containing compound (nitrogen-containing compound including the nitrogen-containing compound A) and water. The first liquid and the second liquid may contain other component blended as necessary. In this case, to enhance dispersibility of the abrasive grains in the first liquid, an arbitrary acid or alkali may be blended in the first liquid to adjust the pH.

The polishing liquid of the (c) multiple liquid type is useful in a case of a combination of components in which polishing characteristics tend to deteriorate in a relatively short time due to aggregation of abrasive grains or the like when mixed. At least one of the liquids (first liquid, second liquid, and the like) may be a concentration type from the viewpoint of cost reduction in storage and transportation. In this case, when the polishing liquid is used, each liquid and water may be mixed. The concentration ratio and pH of each liquid are arbitrary as long as the final mixture can have the same degree of liquid characteristics and polishing characteristics as that of the polishing liquid of the (a) normal type.

### <Polishing Method>

A polishing method of the present embodiment includes a polishing step of polishing a surface to be polished using the polishing liquid of the present embodiment. The polishing liquid used in the polishing step may be a polishing liquid obtained by mixing the first liquid with the second liquid of the above-described polishing liquid set. That is, the polishing method of the present embodiment may include the polishing step of polishing the surface to be polished using the polishing liquid obtained by mixing the first liquid with the second liquid of the above-described polishing liquid set. The surface to be polished may contain silicon oxide, may contain silicon nitride, and may contain silicon oxide and silicon nitride.

The polishing method of the present embodiment may have a form in which the surface to be polished has an uneven pattern constituted of a convex portion (a line portion) and a concave portion (a space portion), and the convex portion contains silicon oxide. The width of the convex portion in the uneven pattern may be 50 μm or less, 40 μm or less, or 30 μm or less. The width of the convex portion in the uneven pattern may be 10 μm or more, 20 μm or more, or 30 μm or more. The sum of the width of the convex portion and the width of the concave portion in the uneven pattern may be 800 μm or less, 700 μm or less, or 600 μm or less. The sum of the width of the convex portion and the width of the concave portion in the uneven pattern may be 400 μm or more, 500 μm or more, or 600 μm or more.

The polishing method of the present embodiment is suitable for polishing a base substrate having a silicon oxide film on a surface thereof in a process of manufacturing a device. Examples of the device include individual semiconductors such as a diode, a transistor, a compound semiconductor, a thermistor, a varistor, and a thyristor; storage elements such as DRAM (dynamic random access memory), SRAM (static random access memory), EPROM (erasable programmable read-only memory), a mask ROM (mask read-only memory), EEPROM (electrical erasable programmable read-only memory), and a flash memory; theoretical circuit elements such as a microprocessor, a DSP, and an ASIC; an integrated circuit element such as a compound semiconductor typified by MMIC (monolithic microwave integrated circuit); a hybrid integrated circuit (hybrid IC); a light emitting diode; and a photoelectric conversion element such as a charge-coupled element.

The base substrate is not limited to the base substrate having only a silicon oxide film on the surface thereof, and may be a base substrate further having a silicon nitride film, a polycrystalline silicon film, or the like on the surface thereof in addition to the silicon oxide film. The base substrate may be a base substrate having an inorganic insulating film such as silicon oxide, glass, or silicon nitride; a film mainly containing polysilicon, Al, Cu, Ti, TiN, W, Ta, TaN, or the like; or the like on a wiring board having predetermined wiring.

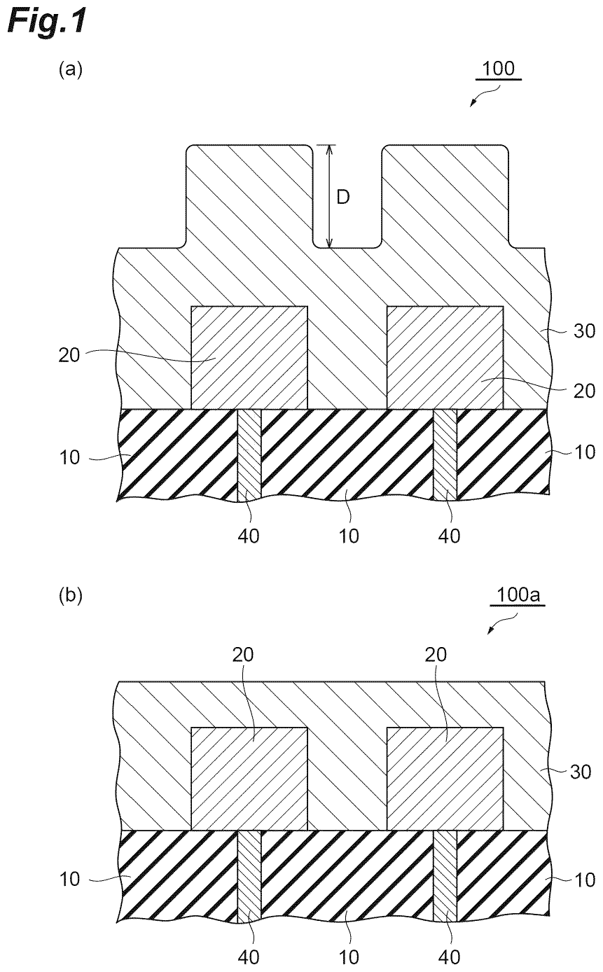

Hereinafter, as an example of a process including the polishing method of the present embodiment, a process of forming an ILD film (an interlayer insulating film) structure by CMP will be described. FIG. 1 is a schematic cross-sectional view illustrating a process of polishing an ILD film, and illustrates a process of forming the ILD film between wiring. FIG. 1(a) is a schematic cross-sectional view illustrating a base substrate before polishing. FIG. 1(b) is a schematic cross-sectional view illustrating a base substrate after polishing.

As illustrated in FIG. 1(a), in a base substrate 100 before polishing, a wiring 20 is formed on a lower substrate (not illustrated) having a predetermined lower wiring (not illustrated) via an ILD film 10, and a silicon oxide film 30 is formed so as to cover this wiring 20. Since the silicon oxide film 30 is formed on the ILD film 10 on which the wiring 20 is formed, a portion on the wiring 20 is higher than other portions, whereby a step D is generated on the surface of the silicon oxide film 30. The wiring 20 is connected to the lower wiring or the like by a contact plug 40 formed so as to penetrate the ILD film 10.

In the process of forming the ILD film structure, to eliminate the step D, unnecessary portions partially protruding on the surface of the silicon oxide film 30 are preferentially removed by CMP. To polish the silicon oxide film 30, the base substrate 100 is disposed on a polishing member so that the surface of the silicon oxide film 30 and the polishing member are brought into contact with each other, and the surface of the silicon oxide film 30 is polished by this polishing member. More specifically, the silicon oxide film 30 is polished by pressing the side of a surface to be polished (surface) of the silicon oxide film 30 against a polishing member of a polishing platen and relatively moving the surface to be polished and the polishing member while supplying a polishing liquid between the surface to be polished and the polishing member. As a result, the step D is eliminated, and finally, as shown in FIG. 1(b), the height of the portion of the wiring 20 on the surface of the silicon oxide film 30 and the height of the other portions become substantially the same as each other, thereby obtaining a base substrate 100a having the silicon oxide film 30 (ILD film) having a flat surface.

As a polishing device used for polishing, it is possible to use, for example, a device having a holder for holding a base substrate, a polishing platen to which a polishing pad is attached, and means for supplying a polishing liquid onto the polishing pad. Examples of the polishing device include a polishing device manufactured by Ebara Corporation (model numbers: EPO-111, EPO-222, F-REX200 and F-REX300) and a polishing device manufactured by Applied Materials (trade names: Mirra3400 and Reflexion). A constituent material of the polishing pad is not particularly limited, and for example, a general nonwoven fabric, foamed polyurethane, porous fluororesin, or the like can be used. In addition, the polishing pad may be grooved such that a polishing liquid accumulates thereon.

The polishing conditions are not particularly limited, but the rotation speed of the polishing platen may be 200 min⁻¹ or less from the viewpoint of preventing the base substrate from flying off. The pressure (processing load) applied to the base substrate may be 100 kPa or less from the viewpoint of easily suppressing polishing scratches on the polished surface. During the polishing, the polishing liquid may be continuously supplied to the polishing pad by a pump or the like. The supply amount for this is not limited, but the surface of the polishing pad may be constantly covered with the polishing liquid. After completion of the polishing, the base substrate may be sufficiently washed in flowing water, water droplets attached to the base substrate may be removed using a spin dryer or the like, and then may be dried.

By polishing as described above, unevenness on the surface can be eliminated, and a smooth surface can be obtained over the entire surface of the base substrate. In addition, a structure having a desired number of layers can be manufactured by repeating a step of forming a film and polishing this film a predetermined number of times.

The base substrate (structure) obtained as such can be used as various electronic components. Specific examples of an electronic component include: a semiconductor element; optical glass such as a photomask, a lens, and a prism; an inorganic conductive film such as ITO; an optical integrated circuit, an optical switching element, and an optical waveguide made of glass and a crystalline material; an end surface of an optical fiber; an optical single crystal such as a scintillator; a solid state laser single crystal; a sapphire substrate for a blue laser LED; a semiconductor single crystal such as SiC, GaP, or GaAs; a glass substrate for a magnetic disk; and a magnetic head.

### <Manufacturing Method and the Like>

The method of manufacturing a component of the present embodiment includes a component preparation step of obtaining a component using a base substrate (a polished member) polished by the polishing method of the present embodiment. The component of the present embodiment is a component obtained by the method of manufacturing a component of the present embodiment. The component of the present embodiment is not particularly limited, but may be an electronic component (for example, a semiconductor component such as a semiconductor package), may be a wafer (for example, a semiconductor wafer), and may be a chip (for example, a semiconductor chip). As one form of the method of manufacturing a component of the present embodiment, in a method of manufacturing an electronic component of the present embodiment, an electronic component is obtained using a base substrate polished by the polishing method of the present embodiment. As one form of the method of manufacturing a component of the present embodiment, in a method of manufacturing a semiconductor component of the present embodiment, a semiconductor component (for example, a semiconductor package) is obtained using a base substrate polished by the polishing method of the present embodiment. The method of manufacturing a component of the present embodiment may include a polishing step of polishing a base substrate by the polishing method of the present embodiment before the component preparation step.

The method of manufacturing a component of the present embodiment may include, as one form of the component preparation step, an individually dividing step of individually dividing a base substrate (a polished member) polished by the polishing method of the present embodiment. The individually dividing step may be, for example, a step of dicing a wafer (for example, a semiconductor wafer) polished by the polishing method of the present embodiment to obtain a chip (for example, a semiconductor chip). As one form of the method of manufacturing a component of the present embodiment, the method of manufacturing an electronic component of the present embodiment may include a step of obtaining an electronic component (for example, a semiconductor component) by individually dividing a base substrate polished by the polishing method of the present embodiment. As one form of the method of manufacturing a component of the present embodiment, the method of manufacturing a semiconductor component of the present embodiment may include a step of obtaining a semiconductor component (for example, a semiconductor package) by individually dividing a base substrate polished by the polishing method of the present embodiment.

The method of manufacturing a component of the present embodiment may include, as one form of the component preparation step, a connection step of connecting (for example, electrically connecting) a base substrate (a polished member) polished by the polishing method of the present embodiment to other body to be connected. The body to be connected to the base substrate polished by the polishing method of the present embodiment is not particularly limited, and may be a base substrate polished by the polishing method of the present embodiment, and may be a body to be connected different from the base substrate polished by the polishing method of the present embodiment. In the connection step, the base substrate and the body to be connected may be directly connected to each other (connected while the base substrate and the body to be connected are in contact with each other), and the base substrate and the body to be connected may be connected to each other via other member (conductive member or the like). The connection step can be performed before the individually dividing step, after the individually dividing step, or before and after the individually dividing step.

The connection step may be a step of connecting a polished surface of a base substrate polished by the polishing method of the present embodiment to a body to be connected, and may be a step of connecting a connection surface of a base substrate polished by the polishing method of the present embodiment to a connection surface of a body to be connected. The connection surface of the base substrate may be the polished surface polished by the polishing method of the present embodiment. By the connection step, a connection body having the base substrate and the body to be connected can be obtained. In the connection step, when the connection surface of the base substrate has a metal portion, the body to be connected may be brought into contact with the metal portion. In the connection step, when the connection surface of the base substrate has a metal portion and the connection surface of the body to be connected has a metal portion, the metal portions may be brought into contact with each other. The metal portion may contain copper.

A device (for example, an electronic device such as a semiconductor device) of the present embodiment has at least one selected from the group consisting of the base substrate polished by the polishing method of the present embodiment and the component of the present embodiment.

### EXAMPLES

Hereinafter, the present disclosure will be described in more detail with reference to Examples, but the present disclosure is not limited to Examples.

### <Production of Cerium Oxide Powder>

40 kg of cerium carbonate hydrate was divided into 10 alumina containers, and each of the containers was fired in air at 830° C. for two hours to obtain a total of 20 kg of yellowish white powder. This powder was subjected to phase identification by X-ray diffraction, and it was confirmed that this powder contained polycrystalline cerium oxide. The particle diameter of the powder obtained by firing was observed by SEM and was found to be in a range of 20 to 100 μm. Next, 20 kg of cerium oxide powder was dry-pulverized using a jet mill to obtain cerium oxide powder. The cerium oxide powder after pulverization had a specific surface area of 9.4 m²/g. The specific surface area was measured by a BET method.

### <Preparation of Slurry>

15.0 kg of the cerium oxide powder obtained as described above and 84.5 kg of deionized water were put in a container and mixed with each other. Next, 0.5 kg of 1 M (mol/L, about 6% by mass) acetic acid was added, and then stirring was performed for 10 minutes to obtain a cerium oxide mixed liquid. This cerium oxide mixed liquid was fed to another container over 30 minutes. Meanwhile, the cerium oxide mixed liquid was irradiated with ultrasonic waves at an ultrasonic frequency of 400 kHz in a pipe through which the cerium oxide mixed liquid was fed.

The above-described cerium oxide mixed liquid fed through ultrasonic irradiation was put into four 500 mL polyethylene containers by 500 g±5 g each. The cerium oxide mixed liquid in each container was centrifuged for two minutes under the condition that centrifugal force applied to the outer periphery was 500 G. After centrifugation was performed, supernatant fractions in the container were collected. The supernatant fractions collected from four containers were mixed with each other to obtain a slurry. The slurry contained cerium oxide particles of about 6.0% by mass based on the total mass of the slurry.

The slurry was diluted with pure water so that contents of the abrasive grains were 1.0% by mass based on the total mass, thereby obtaining a sample for particle diameter measurement. As a result of measuring the average particle diameter of the abrasive grains of this sample using a laser diffraction/scattering type particle diameter distribution measuring device (trade name: Microtrac MT3300EXII manufactured by MicrotracBEL Corp.), the average particle diameter of the abrasive grains was 140 nm.

### <Preparation of Additive>

The following additives were prepared as components contained in the polishing liquid.
1H-indole-3-carboxylic acid
1H-indole-3-acetic acid
1H-indole-3-propionic acid
1H-indole-3-methyl acetate
3-methoxymethylindole
N-acetyl-DL-tryptophan (another name: rac-(αR*)-α-(acetylamino)-1H-indole-3-propionic acid)
5-hydroxy-L-tryptophan
5-hydroxyindole-3-acetic acid
5-methoxyindole-3-acetic acid
8-hydroxyquinoline (another name: 8-quinolinol)
1H-benzotriazole
4-quinoline carboxylic acid
2,6-dihydroxyquinoline
phthalazine
L-proline
Benzohydroxamic acid
Salicylaldoxime
4-hydroxybenzoic acid
1,3,5-trihydroxybenzene dihydrate (another name: phloroglucinol dihydrate)
2-aminobenzaldehyde
L-phenylalanine
3-hydroxy-2-pyridinecarboxylic acid (another name: 3-hydroxypicolinic acid)
5-hydroxy-2-pyridinecarboxylic acid (another name: 5-hydroxypicolinic acid)
5-amino-2-pyridinecarboxylic acid (another name: 5-aminopicolinic acid)
3-pyridine carboxylic acid (another name: nicotinic acid)
6-methyl-2-pyridinecarboxylic acid (another name: 6-methylpicolinic acid)
1H-pyrrole-3-carboxylic acid

### <Preparation of Polishing Liquid for CMP>

A polishing liquid was obtained by mixing the above-described slurry, additives in Tables 1 to 5, a nonionic polymer (polyglycerin, weight average molecular weight: 750, trade name: PGL #750 manufactured by Sakamoto Yakuhin Kogyo Co., Ltd.), a noncyclic alcohol (3-methoxy-3-methyl-1-butanol), and deionized water. Based on the total mass of the polishing liquid, the content of the abrasive grains was 1.0% by mass, the content of the additives in Tables 1 to 5 was 0.10% by mass, the content of the nonionic polymer was 0.20% by mass, and the content of the acyclic alcohol was 8.96% by mass. Each polishing liquid contained acetic acid in a content corresponding to the respective content of abrasive grains as acetic acid mixed at the time of preparing the above-described slurry. The average particle diameter of the abrasive grains in the polishing liquid of each Example was equal to the average particle diameter of the abrasive grains in the above-described slurry.

### <Measurement of Zeta Potential>

An appropriate amount of the polishing liquid was put into the trade name “DelsaNano C” manufactured by Beckman Coulter Inc., and measurement was performed twice at 25° C. An average value of the displayed zeta potentials was obtained as a zeta potential. In each of Examples and Comparative examples, the zeta potential of the abrasive grains was positive.

<Measurement of pH>

The pH of the polishing liquid was measured under the following conditions. The results are shown in Tables 1 to 5.
Measurement temperature: 25° C.
Measuring device: trade name: Model (D-71) manufactured by HORIBA, Ltd.
Measurement method: a pH meter was calibrated at three points using a phthalate pH standard solution (pH: 4.01), a neutral phosphate pH standard solution (pH: 6.86), and a borate pH standard solution (pH: 9.18) as pH standard solutions, an electrode of the pH meter was then placed in the polishing liquid, and pH after stabilization was measured by the measuring device above after 2 minutes or longer passed.

### <Evaluation of Dispersion Stability of Abrasive Grains>

The above-described polishing liquid immediately after the preparation was in a static state for one week (168 hours), and the average particle diameter of the abrasive grains after the lapse of three hours and the lapse of one week immediately after the preparation was measured by the same method as the average particle diameter of the abrasive grains in the above-described slurry. “[(the average particle diameter in the polishing liquid after the lapse of three hours or one week—the average particle diameter of the abrasive grains in the above-described slurry)/the average particle diameter of the abrasive grains in the above-described slurry]×100” was calculated as a change rate of the average particle diameter of the abrasive grains after the lapse of three hours or one week. A case in which the change rate of the average particle diameter of the abrasive grains after the lapse of one week (and the change rate of the average particle diameter of the abrasive grains after the lapse of three hours) was 4% or less was determined as “A”, a case in which the change rate of the average particle diameter of the abrasive grains after the lapse of one week was more than 4% and the change rate of the average particle diameter of the abrasive grains after the lapse of three hours was 4% or less was determined as “B”, and a case in which the change rate of the average particle diameter of the abrasive grains after the lapse of three hours was more than 4% was determined as “C”. The results are shown in Tables 1 to 5.

### <Evaluation of Polishing Characteristics>

The polishing characteristics were evaluated as follows using the above-described polishing liquid.

### (Wafer for Evaluation)

As wafer for evaluation, a non-patterned blanket wafer having a diameter of 200 mm and a silicon oxide film on the surface thereof (BKW, purchased from Advantech Co., Ltd.), and a wafer with a test pattern (PTW manufactured by Hitachi, Ltd.) were prepared.

An initial film thickness of the silicon oxide film of the non-patterned blanket wafer was 1000 nm.

The wafer with the test pattern had a silicon oxide film with fine unevenness and had an initial step in which a convex portion (a line portion) was higher than a concave portion (a space portion) by about 5000 nm, and the shapes of the convex portion and the concave portion were formed by etching the concave portion by about 5000 nm from a state in which the initial film thickness of the silicon oxide film was about 6000 nm. Wiring was a line pattern (pitch: 600 μm width, L/S=30/570 μm, ratio of the area of the convex portion based on the total area of the concave portion and the convex portion: 5%) having the convex portion (the line portion) having a width of 30 μm and the concave portion (the space portion) having a width of 570 μm parallel to each other as a line pattern formed in a die unit of 12 mm×12 mm.

### (Polishing of Silicon Oxide Film)

The above-described wafer for evaluation was polished using a polishing device (trade name: Mirra3400 manufactured by Applied Materials). The above-described wafer for evaluation was set on a holder having a suction pad for attaching a base substrate. A porous urethane resin polishing pad (K-groove, manufactured by DuPont (Dow), model number: IC-1010) was attached to a polishing platen having a diameter of 500 mm.

The above-described holder was placed on the polishing pad while a surface to be polished of the above-described wafer for evaluation faced downward. The inner tube pressure, the retainer ring pressure, and the membrane pressure were set to 14 kPa, 21 kPa, and 14 kPa, respectively.

Then, while the above-described polishing liquid was dropped on the polishing pad attached to the above-described polishing platen at a flow rate of 200 mL/min, the polishing platen and the wafer for evaluation were rotated at 93 min⁻¹ and 87 min⁻¹, respectively, to polish the surface to be polished. The blanket wafer was polished for 30 seconds. The patterned wafer was polished for 60 seconds. Subsequently, the wafer for evaluation after polishing was thoroughly washed with pure water using a PVA brush (polyvinyl alcohol brush), and then was dried.

### (Evaluation of Polishing Characteristics)

Using a light interference type film thickness measuring device (trade name: AFT-5100 manufactured by Nanometrics Japan Co., Ltd.), the amount of change in the film thickness of the silicon oxide film before and after polishing was measured as follows, and the polishing rate was obtained. The results are shown in Tables 1 to 5.

In the blanket wafer, the film thickness change amount was measured at 41 measurement points in total including a center point of the wafer and each point at 5 mm intervals in a diameter direction from the center point (20 points on both sides with the center point as a boundary) (a next measurement point after a measurement point of 95 mm from the center was a position of 97 mm from the center). At these 41 points, the film thickness change amount in the polishing time for 30 seconds was measured, and the average value thereof was obtained as the polishing rate of the blanket wafer.

For the patterned wafer, the film thickness change amount at the convex portion in the region of L/S=30 μm/570 μm was measured to obtain the polishing rate of the patterned wafer. The film thickness change amount at one central portion of the convex portion (a line pattern) formed in the die unit (12 mm×12 mm) at the center of the patterned wafer was measured.

TABLE 1

| | | | | | Dispersion | Polishing rate | | | | |
|---|---|---|---|---|---|---|---|---|---|---|
| | | Additive | | | stability of | [nm/min] | | | Polishing rate ratio | |
| | | | Structural | | abrasive | PTW | BKW | | PTW/BKW | |
| | | Name | formula | pH | grains | SiO₂ | SiO₂ | SiN | (SiO₂) | SiO₂/SiN |
| Example | 1 | 1H-indole-3- carboxylic acid | 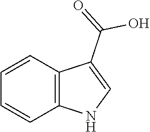 [SMILES: O=C(O)c1c[nH]c2ccccc12] | 4.04 | A | 712 | 598.0 | 137.4 | 1.2 | 4.4 |
| | 2 | 1H-indole-3- acetic acid | 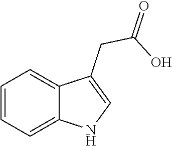 [SMILES: O=C(O)Cc1c[nH]c2ccccc12] | 3.66 | A | 1506 | 129.4 | 9.1 | 11.6 | 14.2 |
| | 3 | IH-indole-3- propionic acid | 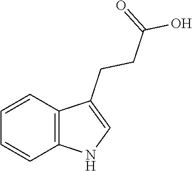 [SMILES: O=C(O)CCc1c[nH]c2ccccc12] | 3.64 | B | 1946 | 43.6 | 3.3 | 44.6 | 13.2 |
| | 4 | 1H-indole-3- methyl acetate | 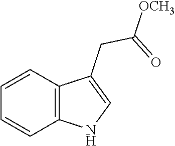 [SMILES: COC(=O)Cc1c[nH]c2ccccc12] | 4.66 | A | 761 | 19.5 | 42.8 | 39.0 | 0.5 |
| | 5 | 3- methoxymethyl indole | 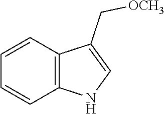 [SMILES: COCc1c[nH]c2ccccc12] | 4.66 | C | 444 | 511.9 | 55.1 | 0.9 | 9.3 |

TABLE 2

| | | | | | Dispersion | Polishing rate | | | | |
|---|---|---|---|---|---|---|---|---|---|---|
| | | Additive | | | stability of | [nm/min] | | | Polishing rate ratio | |
| | | | Structural | | abrasive | PTW | BKW | | PTW/BKW | |
| | | Name | formula | pH | grains | SiO₂ | SiO₂ | SiN | (SiO₂) | SiO₂/SiN |
| Example | 6 | N-acetyl- DL-tryptophan | 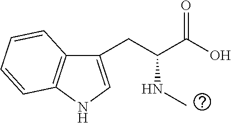 [SMILES: CN[C@H](Cc1c[nH]c2ccccc12)C(=O)O] | 3.23 | A | 2987 | 46.4 | 7.3 | 64.4 | 6.4 |
| | 7 | 5-hydroxy- L-tryptophan | 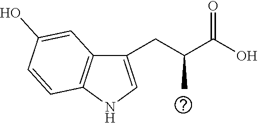 [SMILES: C[C@@H](Cc1c[nH]c2ccc(O)cc12)C(=O)O] | 5.32 | A | 778 | 201.5 | 42.0 | 3.9 | 4.8 |
| | 8 | 5-hydroxyindole- 3-acetic acid | 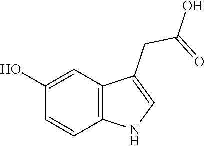 [SMILES: O=C(O)Cc1c[nH]c2ccc(O)cc12] | 3.55 | A | 456 | 189.9 | 1.1 | 2.4 | 172.6 |
| | 9 | 5-methoxyindole-3- acetic acid | 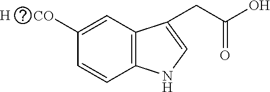 | 3.63 | A | 457 | 73.6 | 8.9 | 6.2 | 8.3 |
| | 10 | 8- hydroxyquinoline | 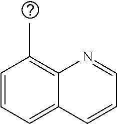 | 6.03 | A | 2363 | 534.1 | 113.7 | 4.4 | 4.7 |

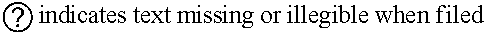

TABLE 3

| | | | | | Dispersion | Polishing rate | | | Polishing rate ratio | |
|---|---|---|---|---|---|---|---|---|---|---|
| | | Additive | | | stability of | [nm/min] | | | PTW/ | |
| | | | Structural | | abrasive | PTW | BKW | | BKW | |
| | | Name | formula | pH | grains | SiO₂ | SiO₂ | SiN | (SiO₂) | SiO₂/SiN |
| Comparative Example | 1 | 1H- benzotriazole | 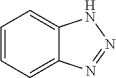 | 4.48 | A | 88 | 19.7 | 39.4 | 4.5 | 0.5 |
| | 2 | 4-quinoline carboxylic acid | 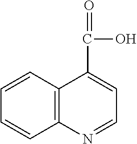 [SMILES: O=C(O)c1ccnc2ccccc12] | 3.51 | A | 254 | 114.7 | 8.2 | 2.2 | 14.0 |
| | 3 | 2,6- dihydroxy- quinoline | 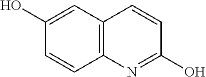 [SMILES: Oc1ccc2nc(O)ccc2c1] | 4.67 | A | 221 | 182.4 | 77.3 | 1.2 | 2.4 |
| | 4 | phthalazine | 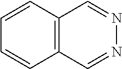 | 5.09 | A | 112 | 73.1 | 124.1 | 1.5 | 0.6 |
| | 5 | L-proline | 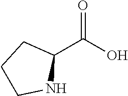 | 4.67 | A | 140 | 519.0 | 0.5 | 0.3 | 1038.0 |

TABLE 4

| | | | | | Dispersion | Polishing rate | | | | |
|---|---|---|---|---|---|---|---|---|---|---|
| | | Additive | | | stability of | [nm/min] | | | Polishing rate ratio | |
| | | | Structural | | abrasive | PTW | BKW | | PTW/BKW | |
| | | Name | formula | pH | grains | SiO₂ | SiO₂ | SiN | (SiO₂) | SiO₂/SiN |
| Example | 11 | Benzohydroxamic acid | 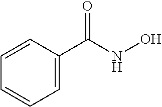 | 4.27 | A | 2137 | 169.8 | 46.2 | 12.6 | 3.7 |
| | 12 | Salicylaldoxime | 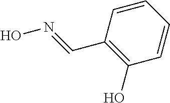 | 3.47 | A | 1350 | 29.7 | 0.2 | 45.5 | 148.5 |
| Comparative Example | 6 | 4-hydroxybenzoic acid | 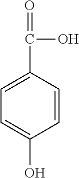 | 3.41 | A | 291 | 196.7 | 8.1 | 1.5 | 24.3 |
| | 7 | 1,3,5- trihydroxybenzene dihydrate | 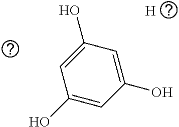 | 4.91 | A | 144 | 108.2 | 74.8 | 1.3 | 1.4 |
| | 8 | 2- aminobenzaldehyde | 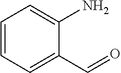 | 5.28 | A | 188 | 68.4 | 107.2 | 2.7 | 0.6 |
| | 9 | L-phenylalanine | 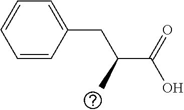 | 4.31 | A | 116 | 58.2 | 77.7 | 2.0 | 0.7 |

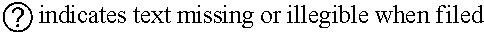

TABLE 5

| | | | | | Dispersion | Polishing rate | | | Polishing rate ratio | |
|---|---|---|---|---|---|---|---|---|---|---|
| | | Additive | | | stability of | [nm/min] | | | PTW/ | |
| | | | Structural | | abrasive | PTW | BKW | | BKW | |
| | | Name | formula | pH | grains | SiO₂ | SiO₂ | SiN | (SiO₂) | SiO₂/SiN |
| Example | 13 | 3-hydroxy-2- pyridinecarboxylic acid | 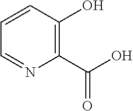 | 3.74 | A | 1360 | 198.3 | 5.4 | 6.9 | 36.7 |
| | 14 | 5-hydroxy-2- pyridinecarboxylic acid | 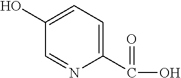 | 3.63 | A | 1210 | 493.7 | 0.9 | 2.5 | 548.6 |
| | 15 | 5-amino-2- pyridinecarboxylic acid | 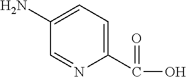 | 4.28 | A | 1427 | 324.8 | 41.2 | 4.4 | 7.9 |
| Comparative Example | 10 | 3- pyridinecarboxylic acid | 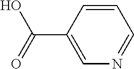 | 3.58 | A | 34 | 116.6 | 7.8 | 0.3 | 14.9 |
| | 11 | 6-methyl-2- pyridinecarboxylic acid | 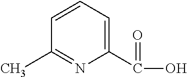 | 4.17 | A | 140 | 263.9 | 58.2 | 0.5 | 4.5 |
| | 12 | 1H-pyrrole-3- carboxylic acid | 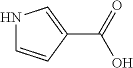 | 3.72 | A | 89 | 127.8 | 9.6 | 0.7 | 13.3 |

### REFERENCE SIGNS LIST

10 . . . ILD film, 20 . . . wiring, 30 . . . silicon oxide film, 40 . . . contact plug, 100, 100a . . . base substrate, D . . . step.

1. A polishing liquid for CMP, the polishing liquid comprising: abrasive grains; a nitrogen-containing compound; and water, wherein
the abrasive grains include cerium-based particles,
the nitrogen-containing compound includes a compound A1 having a fused ring, and
the fused ring has an aromatic five-membered ring with one nitrogen atom.

2. The polishing liquid for CMP according to claim 1, wherein the compound A1 has an indole ring.

3. The polishing liquid for CMP according to claim 1, wherein an alkyl group substituted with at least one selected from the group consisting of a carboxy group and a carboxylate group is bonded to the aromatic five-membered ring.

4. The polishing liquid for CMP according to claim 1, wherein the nitrogen-containing compound includes 1H-indole-3-acetic acid.

5. The polishing liquid for CMP according to claim 1, wherein the nitrogen-containing compound includes N-acetyl-DL-tryptophan.

6. A polishing liquid for CMP, the polishing liquid comprising: abrasive grains; a nitrogen-containing compound; and water, wherein
the abrasive grains include cerium-based particles, and
the nitrogen-containing compound includes a compound A2 having a quinoline ring and one hydroxy group bonded to the quinoline ring.

7. A polishing liquid for CMP, the polishing liquid comprising: abrasive grains; a nitrogen-containing compound; and water, wherein
the abrasive grains include cerium-based particles, and
the nitrogen-containing compound includes a compound A3 having an aromatic ring and a hydroxy group bonded to a nitrogen atom.

8. The polishing liquid for CMP according to claim 7, wherein the compound A3 has a benzene ring.

9. The polishing liquid for CMP according to claim 7, wherein a hydroxyamide group is bonded to the aromatic ring.

10. A polishing liquid for CMP, the polishing liquid comprising: abrasive grains; a nitrogen-containing compound; and water, wherein
the abrasive grains include cerium-based particles, and
the nitrogen-containing compound includes a compound A4 having a nitrogen-containing aromatic ring to which at least one selected from the group consisting of a hydroxy group and an amino group is bonded.

11. The polishing liquid for CMP according to claim 10, wherein the compound A4 has a pyridine ring.

12. The polishing liquid for CMP according to claim 10, wherein at least one selected from the group consisting of a carboxy group and a carboxylate group is further bonded to the nitrogen-containing aromatic ring.

13. The polishing liquid for CMP according to claim 1, wherein the cerium-based particles contain cerium oxide.

14. The polishing liquid for CMP according to claim 1, wherein pH is 3.00 to 7.00.

15. A polishing liquid set for CMP, wherein components contained in the polishing liquid for CMP according to claim 1 are stored separately in a first liquid and a second liquid, in which the first liquid contains the abrasive grains and water, and the second liquid contains the nitrogen-containing compound and water.

16. A polishing method comprising a step of polishing a surface to be polished using the polishing liquid for CMP according to claim 1.

17. The polishing method according to claim 16, wherein the surface to be polished contains silicon oxide.

18. The polishing liquid for CMP according to claim 1, wherein a zeta potential of the abrasive grains is positive.

19. The polishing liquid for CMP according to claim 1, wherein the nitrogen-containing compound includes at least one selected from the group consisting of 1H-indole-3-carboxylic acid, 1H-indole-3-acetic acid, 1H-indole-3-propionic acid, 1H-indole-3-methyl acetate, 3-methoxymethylindole, N-acetyl-DL-tryptophan, 5-hydroxy-L-tryptophan, 5-hydroxyindole-3-acetic acid, and 5-methoxyindole-3-acetic acid.

20. The polishing liquid for CMP according to claim 6, wherein the nitrogen-containing compound includes 8-hydroxyquinoline.
